(19) United States
(12) Patent Application Publication
(10) Pub. No.: US 2018/0376612 A1
(43) Pub. Date: Dec. 27, 2018

(54) ELECTRONIC HARDWARE HOLDER WITH DYNAMIC DENSITY CONTROLLED COOLING

(71) Applicant: Scalematrix, San Diego, CA (US)

(72) Inventors: Mark David Ortenzi, Escondido, CA (US); Chris Orlando, Escondido, CA (US)

(21) Appl. No.: 15/918,245

(22) Filed: Mar. 12, 2018

Related U.S. Application Data
(60) Provisional application No. 62/470,100, filed on Mar. 10, 2017.

(51) Int. Cl. H05K 7/18; H05K 7/20

(52) U.S. Cl. CPC H05K 7/18; H05K 7/20145; H05K 7/20209; H05K 7/20436

(57) ABSTRACT

An electrical equipment cooling rack, has a rack with support rails which extend vertically, a plurality of rackmounted cooling locations or slots, defined within the support rails, each of the cooling locations extending horizontally and stacked one over the other. A first cooled air plenum is on a first side and a second return air plenum on the second side of each of the slots, receiving the air that has passed over the slots. The air is circulated from the return air, across the top, through an air cooler and forced by a fan into the cooled air plenum. An amount of cooling water is controlled, and an amount of fan speed is controlled, based on temperatures, and temperature differentials, and trends in the temperatures.

This application claims priority from provisional application No. 62/470,100, filed Mar. 10, 2017, the entire contents of which are herewith incorporated by reference.

### BACKGROUND OF THE INVENTION

Computing and other equipment can be housed in racks along with other computing equipment. Each item of computing equipment consumes power in its normal operation. Therefore, these racks need cooling.

These racks of computer equipment can often be housed in facilities known as computer data centers which house the electronic hardware in rack based cabinets. These typically include computer room air conditioner units based on distributed air cooled direct expansion (DX) or central air or water cooled chilled water. The location of these units can be along the perimeter of the room (perimeter unit), that are required to cool the entire facility space or next to the cabinet (in-row unit). Other electronic hardware cooling systems include direct-to-chip liquid cooling, immersion oil, and immersion dielectric fluid cooling along with child door implementations that help increase total cooling but need traditional infrastructure design.

The energy involved in operating these conventional cooling systems is significant. Many juristictional authorities have legislated and enforced building energy codes requiring economizing cooling system for computer rooms which bypass the energy intensive refrigerant vapor compressor. This legislation was applied based on traditional cooling of entire facility cubic square feet needed to maintain facility set-points. These economizing systems include direct and indirect air side economizers, waterside economizers, and pumped refrigerant system. These economizing systems add complexity to conventional mechanical cooling systems, thereby increasing risk of failure and reducing reliability. In addition, these systems cannot operate continuously throughout the year and require a full capacity standby refrigerant vapor compression system for backup due to the system's reliance on low outdoor environmental enthalpy conditions, based on traditional facilities designs.

The existing non-conventional hybrid water/air cooled methods reduce the energy consumption required by conventional whole room cooling systems and provide simple economizing alternatives. However, these existing non-conventional alternative cooling methods necessitate non-conventional, custom electronic hardware. Current conventional air cooled electronic hardware requires alterations to operate efficiently in the non-conventional systems. This hardware customization increases the hardware cost, time to deployment, and is not available for all electronic hardware.

### SUMMARY

The inventors recognize that the typical racks which are used in computer systems have drawbacks and the present application addresses many of these drawbacks. One aspect describes techniques which reduce the overall power needed for an electronic cooling system and hence reduces overall energy consumption. At the same time, however, this system provides a dynamic technique of cooling that allows adding more racks to the system in a modular fashion, while preventing so-called hotspots.

The inventors also realize that different racks may belong to computing resources associated with and owned by different entities. It is desirable to close and lock the rack in order to provide individualized security for the items in the rack. However, closing and locking the racks also causes the inside of the rack to be isolated from any cooling that exists in the room.

The present application addresses this issue by describing a special cooling-optimized rack, and also a dynamic density control system for controlling cooling in the racks.

### BRIEF DESCRIPTION OF THE DRAWINGS

these and other aspects will be described in detail with reference to the accompanying drawings: in which:

FIG. 1 shows a basic rack layout for a rack used according to an embodiment from a perspective profile view showing the rack from the side;

FIG. 2 is a perspective posterior view showing the interior back side;

FIG. 3 is a perspective forward surface view showing the interior front side;

FIG. 4 is a visual hardened profile view showing the rack design element locations

FIG. 5 is an isometric view showing compartmentalized component design and locations;

FIG. 6 is a isometric view showing compartmentalized custom enclosure component design showing the cooling dynamics locations

FIG. 7 is a isometric view showing compartmentalized custom enclosure supporting fan and motor integration;

FIG. 8 is a isometric view showing compartmentalized custom enclosure component design revealing the cooling coil location supported by building cooling

FIG. 9 is an isometric view showing compartmentalized custom enclosure component design revealing the cooling calculated volume and curvature of the fan deflector;

FIG. 10 is a front view showing compartmentalize custom enclosure component exterior access panel locations;

FIG. 11 is a is a perspective forward surface view showing compartmentalize custom enclosure component exterior access panel locations;

FIG. 12 is an electronic single-line design view on all controls used, maintaining automated logic design in a pre-configured program;

FIG. 14 is an isometric view showing compartmentalized component design and locations for low voltage cabling or cable management;

FIG. 15 is a perspective design per-laser knock-out rack cable access panel design;

FIG. 16 is a perspective design per-laser knock-out cover plate replacement;

FIG. 17 is a perspective front view of short cable management or low-voltage access panel;

FIG. 18 is a perspective profile view showing of short cable management or low-voltage access panel;

FIG. 19 is a perspective design laser cut-out for cable access or low-voltage panel design; and

FIG. 20 is an isometric view showing compartmentalize custom cable or low voltage wire management.

### DETAILED DESCRIPTION

It will be appreciated that for clarity of illustration, elements illustrated in the figures have not necessarily been drawn to scale. For example, the dimensions of some of the elements are exaggerated relative to other elements.

Embodiments describe an enclosure 200 with cooling and logic for the cooling. The enclosure 200 includes rack mounted locations such as 7 for holding computer equipment. While the preferred embodiment may describe these locations as holding computer equipment, it should be understood that any heat generating electrical equipment could be housed in these racks.

Each of the racks is preferably closeable, and individually cooled according to a special individual cooling and control system which is also described herein. The racks can hold, for example computer servers or other computer hardware as described herein.

An outer steel casing 200, which is shown and described with reference to the other figures is closed and can be locked using a suitable locking system. However, there are also access panels to allow access to the computer equipment, and for maintenance purposes to the cooling equipment.

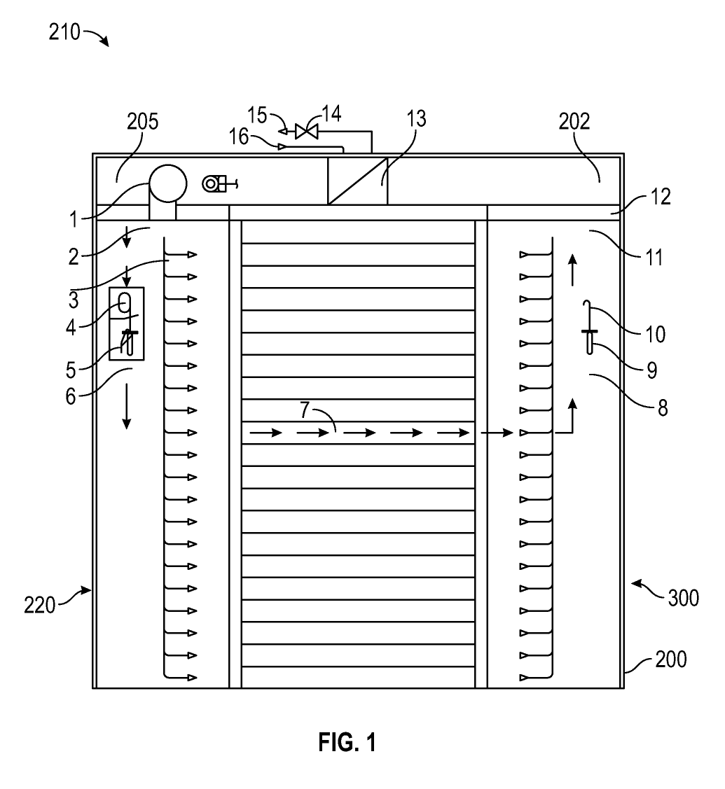

FIG. 1 shows an embodiment showing the assembly shown generally as 300. The assembly includes a bottom part for holding the computer equipment and delivering the cooling, and a top part 210 housing the logic, and receiving and distributing the cooled air.

The assembly includes plural different slots, shown generally as 7, where each slot can hold a computer part, for example an individual server, or some kind of other IT device. The rack also includes a cooling area with cooling system, as described herein. The cooling in the rack is carried out by a motor and fan assembly 1, which receives cooled air that is exchanged within an air cooling plenum 202. The air cooling plenum has a cooled side 205 is itself cooled using a chilled water system, where chilled water is received into the intake 16, and used to cool the air within the chilled side. Water is circulated back through the return side 13, through a system filter 14, and back to the return water to be re-chilled by an external chiller. This chills the air at 205 that is circulated to cool the electronics.

The chilled air at 205 is then forced by the fan 1, through a ducting system at the output 2, generally through the airflow plenum 6. The ducting system forces air through a supply-side air cooling vent 3, which directs the cooled air into each of the different server slots 7.

The temperature of the air going into the server slots is monitored by a sensor 4, which has a first part for that measures the discharge temperature from the fan, and a second part 5 that measures the airflow as it discharges to the different slots.

The air is forced through each of the server slots, across each server at 7 to return air plenum 8. The return air plenum 8 includes a return temperature sensor 9, and an AI return temperature sensor 10. The air is then returned through a system filter 12, to the return side of the cooling plenum 202.

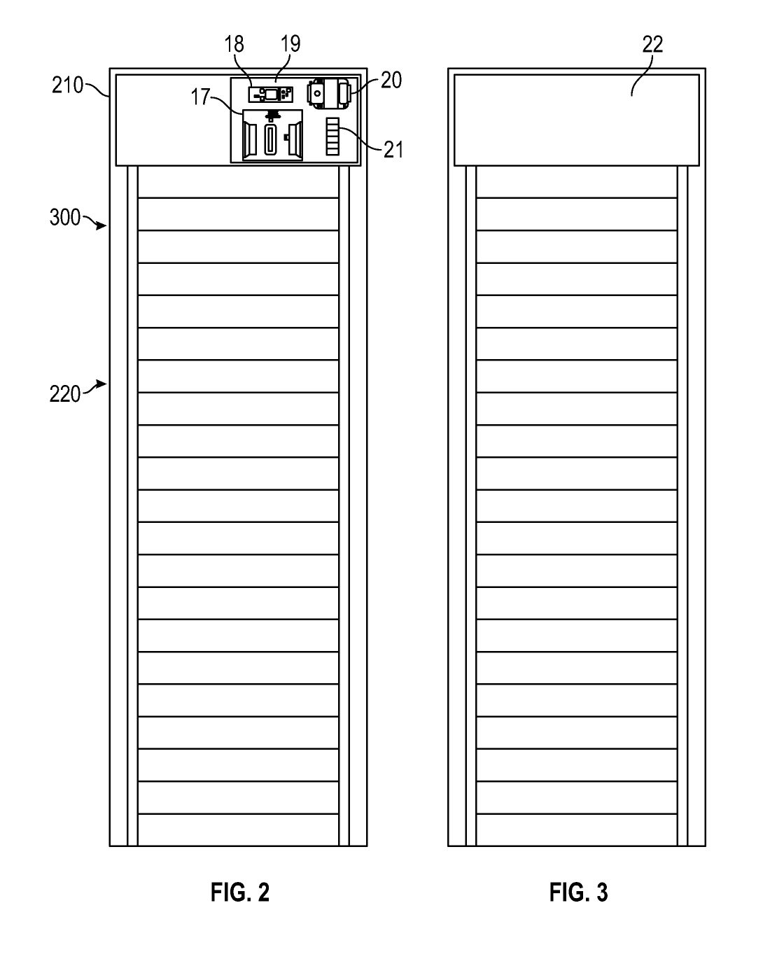

Each rack also includes an automation controller 17 which is shown generally in FIG. 2. The automation controller 17 includes a relay 18 mounted on a system mounted board, that monitors individually the temperature and monitors the access to the rack 300.

FIG. 3 shows how the controller and cooling is covered by a cover 22.

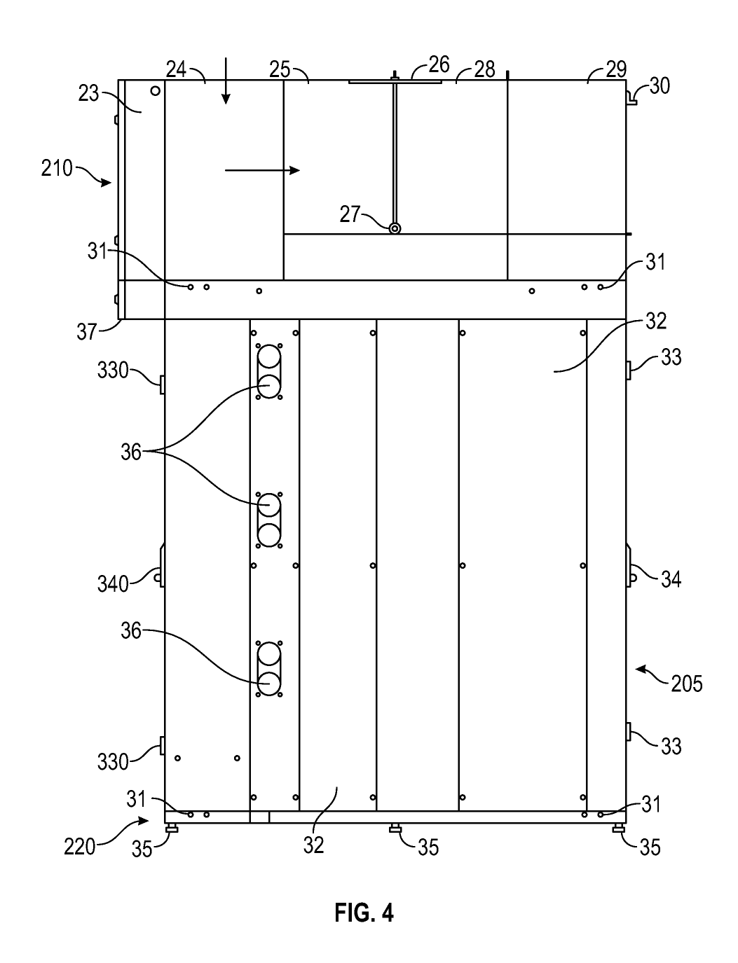

FIG. 4 shows further details on the layout of the rack. The rack top part 210 includes logic and cooling controls. Environmental control box 23 controls how the environment is maintained within the inside of the rack. This environmental control box may include the controller 17 that provides controls for the cooling. The discharge air is received into the discharge air side channel 24, where it passes through a discharge coil 25, into the airflow plenum 6 as previously described. The condensation drain 27 can collect the condensation from the cooled air. There is also return air system 28 which receive the return air after it has been circulated through the system. The return air is received from the return air side channel 29, from the return air plenum 8 as previously described.

An upper seismic support 31 can connect the rack to a support to avoid tipover.

As shown, there are hinged doors on both the front and rear of the rack. Door hinges shown as 33 and door handles 34 are located on both sides. The rack itself is located on leveling feet 35 at the bottom of the rack.

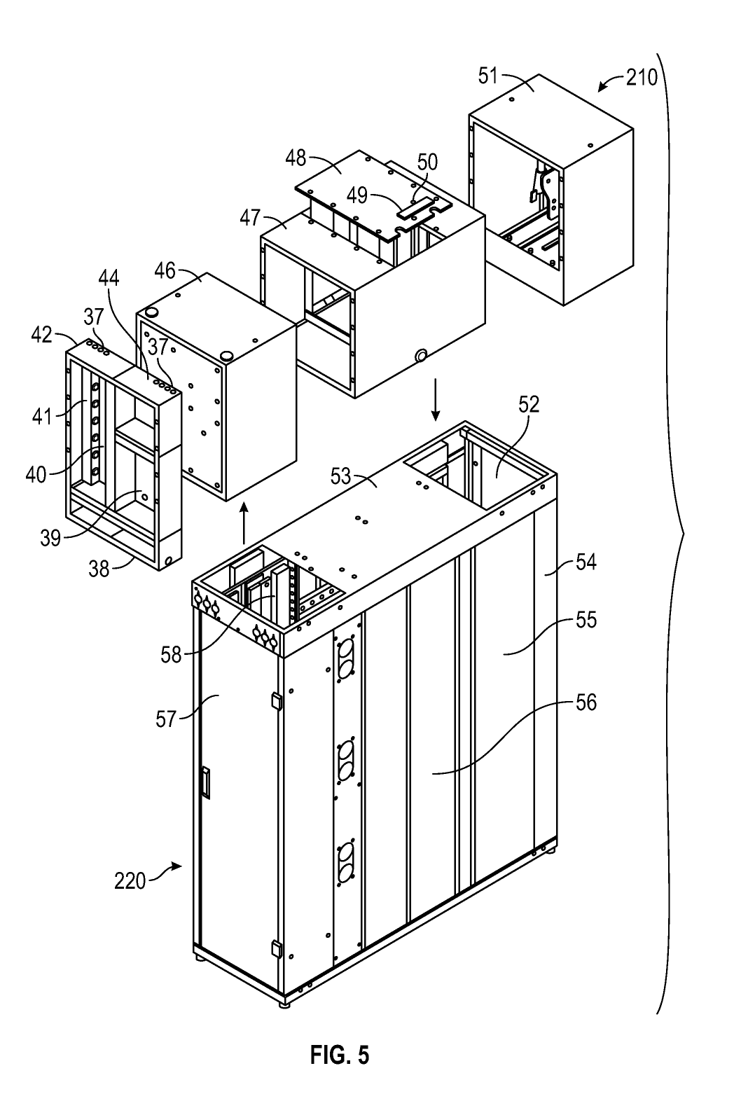

FIG. 5 shows a cut out view of the rack, showing the different parts which are connected together to form the rack top 210. Power inlet access is provided in the power access box 37, through the inlet access 38. There is also a housing for the control portion or a housing 39 for the control portion that is shown generally in FIG. 2. The control system also includes a fire suppression access box 40, which includes a wire panel 41. Together, the power access, fire suppression and control access collectively form a control box assembly 42. The control box assembly 42. The control box assembly 42 also includes a shunt trip control box 44.

The rack top 210 also includes the discharge air channel, which connects, as shown, to the discharge air channel 58/plenum 6, on the bottom rack portion 220. The discharge air channel 46 receives air that has been cooled by the coil assembly 47. Air coil section 47 includes a coil top part, 48, that is connected to receive cooling water. There is a water seal 49, connected down by a wingnut connection.

The other side of the air coil 47 section receives the discharge air from the return air side channel 51. That air is again cooled as it passes over the coil 47 to complete the flow of air.

In operation, the fan blows air down from the discharge air part 46 into cooled air plenum 6, whereby the cooled air is driven across the electronics in slot 7, and taken up by the return air plenum 8. The air in the return air plenum 8 returns to the return air part 51, and is passed across the cooling coil in 47. This cools the air, before it is returned by 46 into the cooled air plenum 6. The amount of cooling, and the speed of the fan, controls the amount of cooling of the electronics.

The rack bottom 220 includes a top panel 53 which is a structural member supporting the rack sides. The top panel 53 extends between the discharge air channel 58 and the supply air channel 52. A front rack support 54 includes the structure that can hold the computer components in place. There is also a removable side panel 55 on the discharge side, and another removable side panel 56 on the return side. A return side door holds the rack work closes the rack on the return side, enabling the rack to be open from either the front or the back.

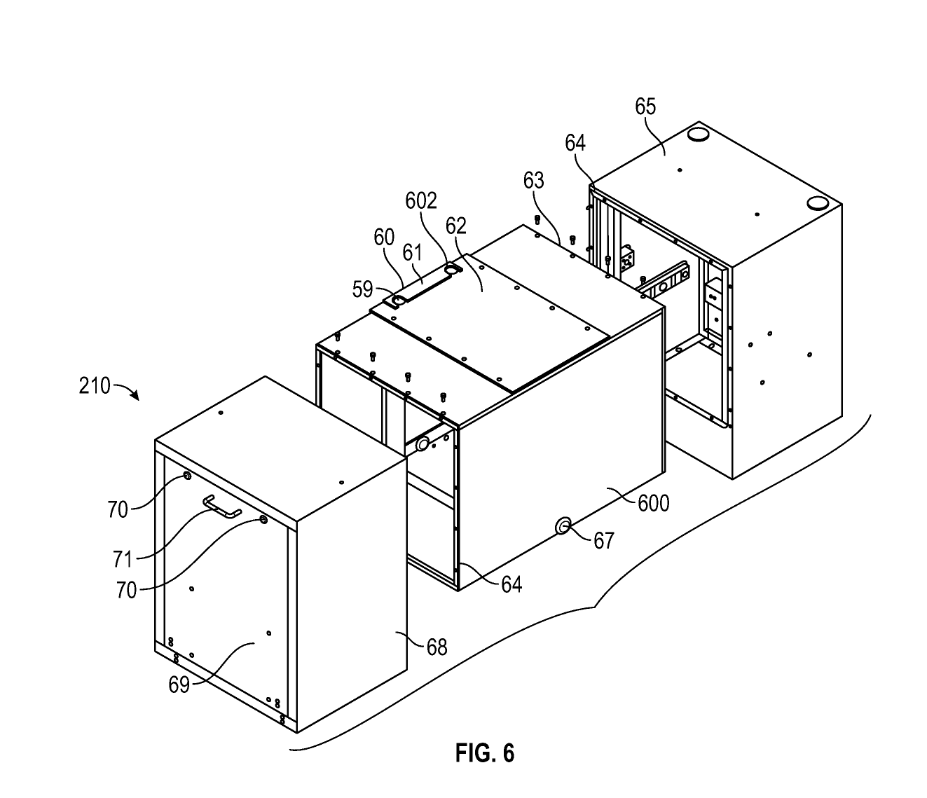

FIG. 6 shows the mechanical layout of the rack top portion 210. The top rack portion 210 includes the cooler assembly portion 600, which includes the chilled water supply 59, and the chilled water return 602. The supply and return are held in place by a cover plate 60, screwed down by a botfly nut 61.

The coil is covered by a removable cover plate 62. The inside of the cooler assembly portion 600 forms a channel for air that is passed from the return air plenum, cooled as it passes over the coil to be delivered to the cooled air plenum. The channel portion 63 connects to the return air channel 65 via the connection. The return air channel 65 is open at the bottom to supply air to the return air channel.

The condensation outlet 67 in the cooler assembly portion 600 exhausts the condensation from the assembly. The cooler assembly 600 also connects to a discharge air channel 68 which includes the fan 700 inside the channel 68. The fan is attached to a fan access door 69 with a secure lock 70 and a handle 71.

The door 69 is shown in more detail in FIG. 7, which shows the door 69 in the open position. The door in this embodiment is hinged on a hinge 72. The fan 700 is mounted inside the door on a fan mounting bracket 73, so the fan moves as the door opens and closes. The fan discharges in the direction 702, so when the door 69 is closed, this discharges air towards the bottom as shown in FIG. 7. The door opens with a shoulder hinge arm 74 holding the door 69.

The coil box as shown in the coil box 600 is shown in further detail in FIG. 8. This includes the coil 81, covered by the coil cover 82. The supply and return inlets 83 84 are connected to the coil and held by plate 85 and wingnut 86. Coil guides 87 hold the coil into place, placing it into the inlet portion of the coil cover.

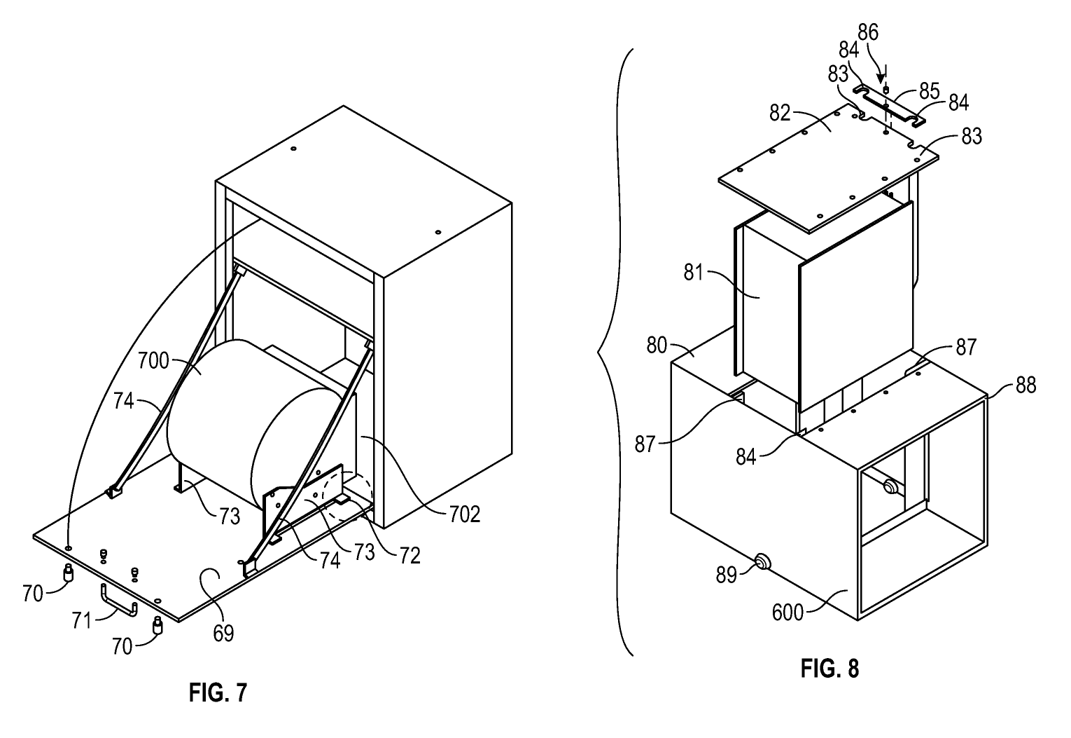

A fan deflector is shown in FIG. 9, which shows an inlet door 90 which is sealed around its edges by an inlet door seal 91. The space defined within 93 defines an enclosure, that is connected to an air deflector 94.

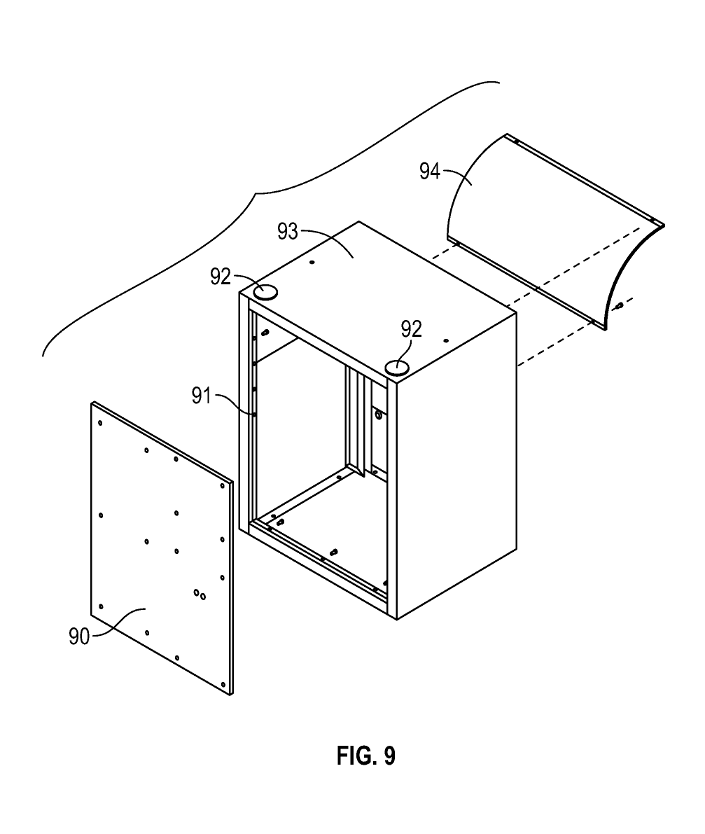

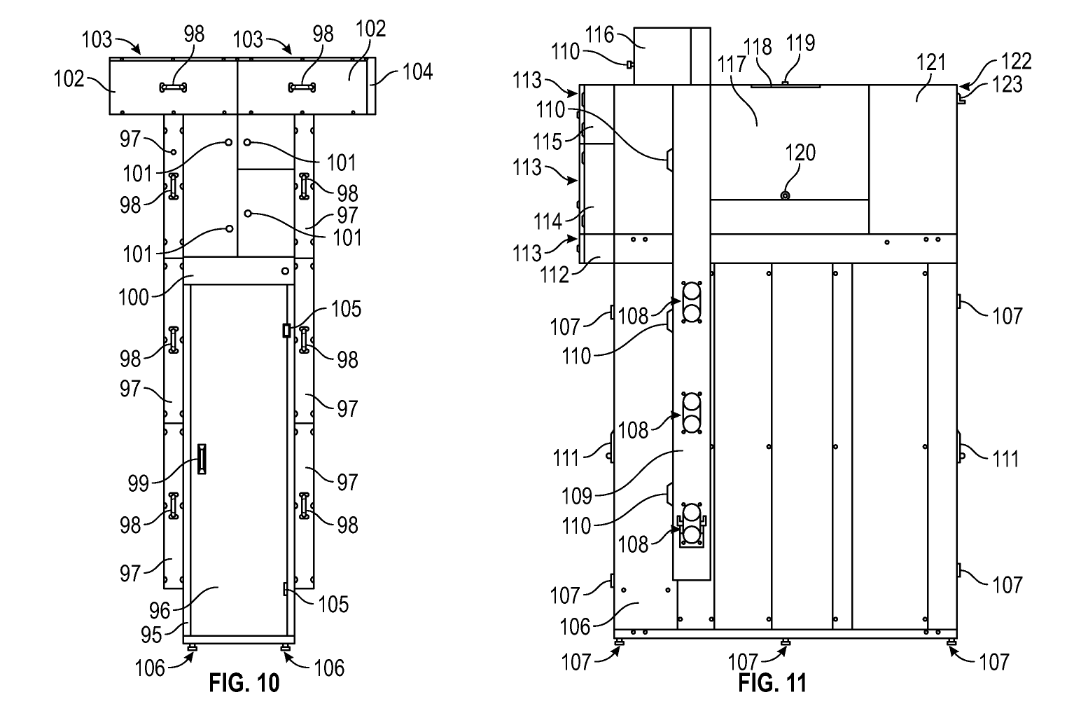

FIGS. 10 and 11 show further layouts of the device, showing how the rack includes different handles at the different locations.

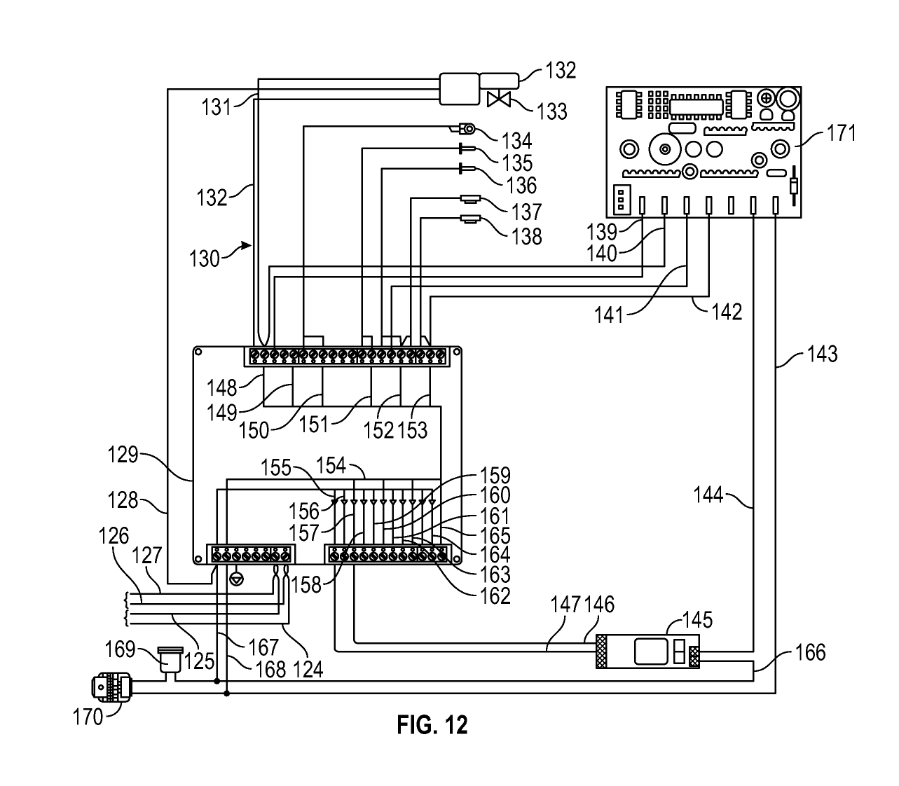

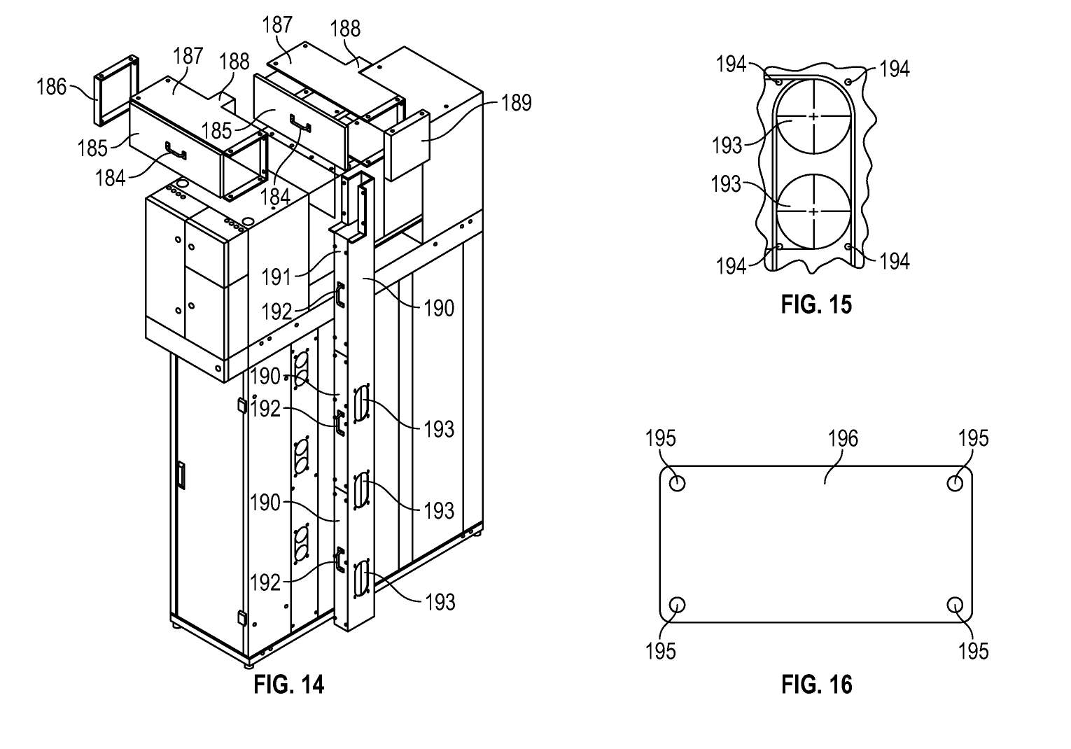

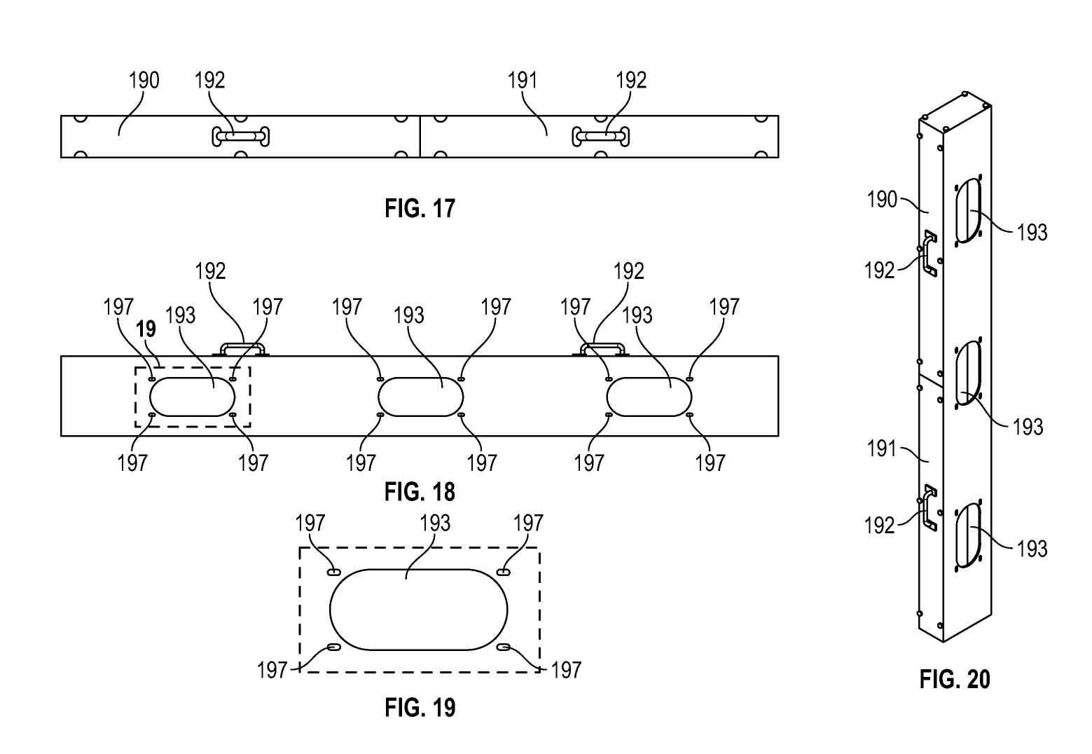

FIG. 12 illustrates the control flow of the system, as described herein. The controller 129 includes various inputs thereto, including at least the fan input line 129 which indicates whether the fan is running. The controller also produces a number of outputs to control the cooling. Output 130 controls the water valve 133 to turn on more or less of the water flow depending on the temperature and heat load. The fan is controlled through a current sensing relay that monitors the fan status. The temperature controllers as previously described, monitor the temperature 135 of the discharge air, 136 of the return air, 137 of the chilled water supply and 138 of the chilled water return. The speed of the fan is monitored via input 139, and the RPM of the fan is monitored via input 141. Based on all the inputs, the fan is enabled for operation, and the water supply is turned on and off and controlled, depending on the temperatures as described herein. FIGS. 14 through 17 show further details of the assembly.

In operation, the inside of the rack includes spots for holding an cooling computer and different computer (and other electrical heat generating equipment). The present invention comprises a rack mount enclosure cabinet with an integrated coil designed liquid cooling heat transfer, in conjunction with smart logic cooling system.

The fan 1 as described herein can be a multi-staged VFD “Variable Frequency Drive” motor that works in conjunction with the water value at the top of rack, based on water temperature supply side cooling.

In embodiments, the controller can be a eHoneywell PW64389 Unitary Controller that works in conjunction with a Honeywell WEP-700-1 that has the ability to stage the motor speed of the fan, and the turn on level of the valve control to work in conjunction with the rack power demand. In this way, more cooling is supplied when more power is being consumed in the rack. When less power is consumed in the rack, the cooling is decreased, thus reducing the load on the water chiller and thus reducing the overall cooling requirements.

The sequence of operations:

The “DDC” Dynamic Density Control rack controller, 129 monitors the discharge air and the return air from the equipment IT load within the self-contained rack. The controller modulates the chilled water valve 133 and fan as described herein, based on the specific temperature differential between the chilled air and the return air. For example, a chilled air temperature which is 10 degrees higher than a desired chilled air may cause the chilled water valve to open more, to lower the temperature of the chilled air. A higher overall temperature, or differential between chilled air and return air may cause the fan to increase its speed. Each of these logic states can cause changes to the cooling water amount delivered to the coil, and also to the fan speed, according to specific set-points. This is adjusted automatically based on return air temperature versus set-points. The “DDC” Dynamic Density Control 129 also control the fan start/stop and speed as well as monitor fan speed feedback based on RPM. Each controller is programed with 10 demand limits flags that allow for set-point bumps at different levels/demand, adjustable per controller from the EMS when required. At any point and time based on the thresholds that are configured, up to 52 KW Kilowatts of power can be temperature-controlled at peak sustained loads.

The “DCIM” Data Center Infrastructure Manager works in correlation with the facilities cooling systems. This allows all chilled water distribution that feeds from the facility chillers to the racks that maximizes efficiencies across multiple factors. This will supply the correct amount of PSI/GPM to cool the rack load at any given time across all the rated power distributions. All data adjustments are made every 3 minutes based on IT or power load, with the ability to use many different cooling levels required in a N/N+1/N+2 configuration.

The increase (and decrease) of the cooling is based on hardware points, software points, trend points, and alarms. The DDC monitors the discharge air and return air from the equipment rack and modulates the chilled water valve to discharge air based on the setpoints. The DDC also monitors and controls the fan start stop speed as well as monitoring. In one embodiment, the return air temperature can be a hardware point. When, for example, the return air temperature exceeds a first threshold value such as 90° F., this causes a first bump to increase the fan RPM by a first amount such as 200 RPM to promote additional cooling. When the return air temperature exceeds a second value such as 110°, this also causes a second bump, to increase the amount of cooled water. There can be additional bumps, to further increase the fan RPM and/or the return air temperature. The cooled air temperature can similarly be monitored.

The bumps can also be caused by trends. For example, when the return air temperature begins rising by more than 2° F. in any thirty second period, this may automatically cause a first bump, or second bump.

The supply air temperature similarly is monitored. The supply air temperature should be kept around 70° F. in one embodiment. When this supply air temperature is higher than 75° F. that amount, it means that not enough cooling has been provided, thus causing the cooled water to be increased. Similarly, a trend alarm can be set off when the cooled air temperature rises by 2° F. in any 60 second period to either or both of increase cooled water or increase fan speed.

The supply fan RPMs are also monitored, which can cause which can be monitored to set off an alarm. Alarms can also be set off by too high return air temperature, too high a supply temperature, too high a zone temperature overall, or too low temperature in any location. Any temperatures, for example, less than 40° F. could set off a low return air temperature, causing either supply cooling to be reduced, or even causing heating if too cold.

The self-contained rack design is based on a Nema-3 enclosure that forces airflow from the top of the unit, down and across all the heat loads, and back across the coil to be cooled again. The amount of cooling is dynamically balanced based on cooling and heating dynamics. The rack design is based on an 18 in. plenum in front of the intake side of the IT/Server hardware and exhausted through the back of the servers on the return side of the rack, which also supports an 18″ plenum. Both

The size of the plenum is based on airflow requirements that are need to support 52 Kw @ 3500 CFM without restriction preventing back-flow concerns. The dual coil or single coil design is deployed at top of rack, allowing the forced air side of the rack to use cooling from top of rack to compensate for hot air rising, to supply the cooled air from the top. The rack is able to maintain a delta of 1 to 2 degrees from the top of the rack to the bottom of the rack, allowing constant temperature throughout the supply side of the server rack. Positive air pressure is maintained at 1 to 2 pounds by the fan, with the ability to blow-by releasing over 3 pounds, maintaining constant pressure, while not overdriving server fans.

All control wiring is concealed using tamper proof raceways between wall mounted electronics and mechanical hardware that have also been isolated from each device by separate compartments. This allows the isolation of low voltage and high voltage in the same containment area.

All controls are located on outside of the rack contained in multiple nema 3 enclosures, maintaining ambient cooling and the ability to preserve gear without entering rack enclosure. Cabinet to cabinet cable management has been designed in a couple different fashions giving the ability for cabinet to cabinet with 4″×4″ gutters with secure and removable face plates, concealing and maintaining integrity between racks. This is installed between cabinet using laser knock-outs for pass-through with associated brush material preventing blow-by in between racks. For multiple rack cable management, a different design has been created using a 4″×6″ inter-cabinet with a larger 12″ gutter that interlocks at the top of rack with the ability to extend in either direction allowing any rack deployment configuration. All electronics have been isolated and built with the ability for quick disconnect and easy replacement.

Air filtration is used as described herein, keeping any contaminants that might have entered the rack during any IT maintenance that might have occurred during that time, continuing to keep rack a clean environment. Fire suppression has also been installed that supports temperature release activation at 220 degrees with shunt trip capability or none-trip based on the customer requirements. The top of rack box enclosure has been developed to support this design and isolates the power from the low voltage infrastructure.

Preset temperature thresholds which are maintained using ladder logic that was developed to maintain cooling, based on multiple input and monitoring systems. Based on the temperature of that rack that has been predetermined based on the input or supply and return temperature, automated logic will keep the system at a constant temperature based on multiple factors, not to exceed 52 KW. Having systems that control all cooling from the central cooling plant, pumps, top of rack value control and fan speed, allows the rack and facility to operate at a 30% more efficient infrastructure when cooling the IT load. This optionally replaces the conventional refrigerant vapor compression based computer room air conditioning (CRAC) systems, which generally cool the entire square footage of a facility.

Although only a few embodiments have been disclosed in detail above, other embodiments are possible and the inventors intend these to be encompassed within this specification. The specification describes certain technological solutions to solve the technical problems that are described expressly and inherently in this application. This disclosure describes embodiments, and the claims are intended to cover any modification or alternative or generalization of these embodiments which might be predictable to a person having ordinary skill in the art. For example, other sizes of plenums and fans can be used.

In one or more exemplary embodiments, the functions described may be implemented in hardware, software, firmware, or any combination thereof. If implemented in software, the functions may be stored on or transmitted over as one or more instructions or code on a computer-readable medium. Functions can also be carried out by programmed computer readable media which can be an article comprising a machine-readable non-transitory tangible medium embodying information indicative of instructions that when performed by one or more machines result in computer implemented operations comprising the actions described throughout this specification.

Also, the inventor(s) intend that only those claims which use the words “means for” are intended to be interpreted under 35 USC 112, sixth paragraph. Moreover, no limitations from the specification are intended to be read into any claims, unless those limitations are expressly included in the claims.

Where a specific numerical value is mentioned herein, it should be considered that the value may be increased or decreased by 20%, while still staying within the teachings of the present application, unless some different range is specifically mentioned. Where a specified logical sense is used, the opposite logical sense is also intended to be encompassed.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An electrical equipment cooling rack, comprising
a rack, having support rails which extend vertically,
a plurality of rackmounted cooling locations, defined within said support rails, each of the cooling locations extending horizontally and stacked one over the other;
surfaces on an inside of said rack defining a first cooled air plenum on a first side of each of said rackmounted cooling locations, and a second return air plenum on the second side of each of the rackmounted cooling locations, where the first plenum and the second plenum are separated by the rackmounted cooling locations; where the return air plenum receives air that has passed through the rackmounted cooling locations;
an air cooling plenum, at a top portion of the rack, defined above all of the rackmounted cooling locations, the air cooling plenum having a first side receiving the return air from the second return air plenum on the second side of each of the rackmounted cooling locations, and having a second side delivering cooled air to the first cooled air plenum on the first side of each of said rackmounted cooling locations;
said air cooling plenum including a first section receiving the air from the second plenum, delivering air to a water cooled air cooling structure to produce cooled air that is delivered to a second section separated from the first section by the air cooling structure, and having a fan forcing air from the second structure into the cooled air plenum first cooled air plenum on the first side of each of said rackmounted cooling locations.

2. The rack assembly as in claim 1 further comprising an electrical controller, which controls operation of the cooling.

3. The rack assembly as in claim 1, wherein the fan forces air from the second structure in a downward direction through the first cooled air plenum to the rackmounted cooling locations.

4. The rack assembly as in claim 2, further comprising a first cooled air temperature sensing part located for sensing air in the cooled air plenum, and a second cooled air temperature detecting part located for sensing air in the return air plenum.

5. The rack assembly as in claim 4, wherein the air temperature sensing parts detect both a temperature of air, and also an amount of flow of the air.

6. The rack assembly as in claim 4, wherein the electrical controller controls an amount of cooling water supplied to the air cooling structure, and also controls operation of the fan, based on said air temperature sensing parts.

7. The rack assembly as in claim 6, wherein the electrical controller increases only one of the amount of water supplied and a speed of the fan when a differential between the cooled air temperature and the return air temperature exceeds a first certain amount, but does not exceed a second certain amount greater than the first certain amount.

8. The rack assembly as in claim 7, wherein the electrical controller increases both of the amount of water supplied and the speed of the fan when the differential between the cooled air temperature and the return air temperature exceeds the second certain amount greater than the first certain amount.

8. The rack assembly as in claim 5, wherein the electrical controller increases only one of the amount of water supplied or the speed of the fan, but not both, based on a differential between the cooled air temperature and the return air temperature exceeding a first certain amount, but not exceeding a second certain amount greater than the first certain amount.

9. The rack assembly as in claim 8, wherein the electrical controller increases both of the amount of water supplied and the speed of the fan based on a the differential between the cooled air temperature and the return air temperature the second certain amount greater than the first certain amount.

10. The rack assembly as in claim 5, wherein the electrical controller increases one of the amount of water supplied or the speed of the fan, but not both, based on a differential between the cooled air temperature and the return air temperature increasing at a first rate but not exceeding a second rate greater than the first rate.

11. The rack assembly as in claim 10, wherein the electrical controller increases both of the amount of water supplied and the speed of the fan, but not both, based on the differential between the cooled air temperature and the return air temperature increasing at the second rate greater than the first rate.

11. The rack assembly as in claim 1, wherein the air cooling structure is a coil that is supplied with cooled water.
